(19) United States
(12) Patent Application Publication
(10) Pub. No.: US 2012/0097328 A1
(43) Pub. Date: Apr. 26, 2012

(54) APPARATUS FOR FABRICATING SEMICONDUCTOR WAFERS AND APPARATUS FOR THE DEPOSITION OF MATERIALS BY EVAPORATION USING A MOLECULAR BEAM

(75) Inventors: Jerome Villette, Le Plessis Robinson (FR); Valerick Cassagne, Limours En Hurepoix (FR); Michel Picault, Boulogne-Billancourt (FR)

(73) Assignee: RIBER, Bezons (FR)

(21) Appl. No.: 13/380,262

(22) PCT Filed: Jun. 23, 2010
(86) PCT No.: PCT/FR2010/051280

§ 371 Date: Dec. 22, 2011

(30) Foreign Application Priority Data
Jun. 23, 2009 (FR) 0954254

(51) Int. Cl. H01L 21/02; C23C 16/448

(52) U.S. Cl. 156/345.1; 118/723 VE

(57) ABSTRACT

Described is equipment for depositing materials by evaporation using a molecular beam and equipment for fabricating semiconductor wafers, including a central conveyor module having a plurality of lateral ports capable of functioning under vacuum pressure conditions above 10⁻⁸ Torr. The semiconductor wafer fabrication equipment includes a loader module and one or more substrate treatment modules functioning under vacuum pressure conditions above 10⁻⁸ Torr, each treatment module being connected to one of the ports of the central conveyor module. The fabrication equipment includes at least one module for depositing materials by evaporation using a molecular beam operating under vacuum pressure conditions below 10⁻⁸ Torr, the molecular beam deposition module being connected to one of the ports of the central conveyor module and being capable of receiving the substrate in order to deposit a layer of materials on its face to be treated.

The invention relates to the field of microelectronics.

More particularly, it pertains to equipment for fabricating semiconductor wafers and to equipment for depositing materials by evaporation using a molecular beam for fabricating semiconductor wafers.

The majority of electronic and microelectronic components such as magnetic memories, complementary metal oxide on silicon (CMOS) circuits or processors are produced with the aid of stacks of thin layers of materials with very high purity. The deposited materials are, for example, conductors (metals), semiconductors (silicon, germanium, III-V or II-VI type compounds, for example) or insulators (oxides, nitrides, for example). They are deposited onto substrates of silicon or germanium or other materials. Said substrates are disk-shaped with diameters of 200 mm [millimeter] or 300 mm. Other substrate shapes are also possible.

Each substrate undergoes a plurality of treatment steps, such as depositing one or more layers of materials, heat treatment, or etching. A semiconductor disk or wafer is thus produced that is subsequently treated to obtain a multitude of electronic components.

In the microelectronics industry, such steps are conventionally carried out in a multi-chamber system under vacuum (down to approximately 10⁻⁷ Torr). Each of the steps of the process is carried out in a distinct chamber or module. Each chamber is associated with an operation of depositing layers of materials, heat treatment, or etching. A robotic arm placed in a vacuum chamber transports the substrates from one chamber to another.

Technological requirements for reducing the scale of electronics components and for improving the performance of integrated circuits in terms of electricity consumption and speed mean that it is becoming necessary to produce thinner layers of materials using novel materials with higher purity or structural (crystalline) quality.

The use of semiconductor alloys such as III-V or II-VI type semiconductor and depositing layers of materials a few atomic layers thick formed from a high quality material can satisfy these needs.

Known techniques of depositing materials by evaporation using a molecular beam such as techniques of the molecular beam epitaxy deposition (MBE) or molecular beam deposition (MBD) type make it possible to achieve said performances.

Such techniques require ultra-vacuum pressure conditions, i.e. a pressure in the reaction chambers of less than 10⁻⁹ Torr, in order to avoid contaminating the substrate, the various layers, and the various interfaces.

The deposition of thin layers onto a substrate has been envisaged using equipment for depositing materials by evaporation using a molecular beam, and then transferring the substrate into another piece of equipment that is a multi-chamber system used in the microelectronics industry to produce other deposits or to carry out other treatments. However, exposing the layers or interfaces to high vacuums or to neutral atmospheres or to air between the depositions or treatments has a deleterious effect on the final quality of the electronic devices.

Known techniques for depositing materials by evaporation using a molecular beam are incompatible with conventional multi-chamber systems used in the microelectronics industry.

Techniques for depositing materials by evaporation using a molecular beam generally use a single deposition chamber that is capable of depositing many materials and alloys, for example AsGa, InGaAs, or InP, doped or otherwise, but the multi-chamber systems used in the microelectronics industry require a plurality of reaction chambers in which one or sometimes more materials or alloys are deposited, but still in a limited number in order to avoid extraneous contamination.

Further, in order to be able to be used in the fabrication lines of the silicon industry, multi-chamber systems must comply with Semiconductor Equipment and Materials International (SEMI) standards. In particular, said systems must function under conditions of vacuum pressure or of pressure above 10⁻⁸ Torr. The substrate size is standardized (200 mm, 300 mm or 450 mm in diameter). There are also constraints as regards the dimensions of the chambers, the electronics, and the software controlling the various pieces of equipment (robots, sources, for example).

MBE or MBD systems generally use solid materials placed in crucibles (or evaporation sources) that are evaporated under vacuum by heating with filaments or by electron bombardment. The majority of the materials are in the liquid state during evaporation, and so the crucible is generally placed approximately vertically at the bottom of the reaction chamber. The substrate is placed above the crucibles with the face to be treated facing the evaporation sources, i.e. oriented downwards.

In contrast, in the multi-chamber systems used in the microelectronics industry, the substrate is positioned with its face to be treated directed upwards.

Further, the reactors of MBE or MBD systems are bulky since they use a large number of evaporation sources and have large source/substrate geometry in order to produce deposits with thickness of high precision that may be down to one layer of atoms, over large surface areas of up to 500 mm in diameter, thus requiring large-diameter reactors. It is impossible to integrate them unchanged into a multi-chamber system as used in the microelectronics industry.

Thus, one aim of the invention is to provide equipment for depositing materials by evaporation using a molecular beam for fabricating semiconductor wafers, which equipment is more compact and compatible with the multi-chamber systems of the microelectronics industry.

Another aim of the invention is to provide equipment for fabricating semiconductor wafers that can be used to carry out all of the deposition and treatment steps on the semiconductor wafer in situ.

The invention relates to equipment for fabricating semiconductor wafers, each comprising a substrate covered with at least one layer of materials, said substrate comprising a face to be treated A and an untreated face B, the fabricating equipment comprising:
a central conveyor module comprising a plurality of lateral ports and conveyor means that can convey said substrate from one lateral port to another, said central conveyor module being capable of functioning under vacuum pressure conditions above 10⁻⁸ Torr;
a loader module connected to one or more ports of the central conveyor module, said loader module being capable of receiving one or more substrates; and
one or more treatment modules for treating the substrate functioning under vacuum pressure conditions above 10⁻⁸ Torr, each treatment module being connected to one of the ports of the central conveyor module and being capable of receiving said substrate in order to carry out a treatment operation on its face to be treated A.

According to the invention, the fabricating equipment comprises:
at least one molecular beam deposition module for depositing materials by evaporation using a molecular beam functioning under vacuum pressure conditions below 10⁻⁸ Torr, said molecular beam deposition module being connected to one of the ports of the central conveyor module and being capable of receiving said substrate in order to deposit a layer of materials on its face to be treated A.

In various possible embodiments, the device of the invention may also be defined by the following characteristics that may be considered in isolation or in any of their technically feasible combinations, and that provide respective specific advantages:
said module for depositing materials by evaporation using a molecular beam includes an airlock connecting it to one of the ports of the central conveyor module, said airlock allowing the pressure between the module for depositing materials by evaporation using a molecular beam to be made compatible with the central conveyor module, said airlock including an opening in each of its lateral ends that can be closed by a valve, and pump means that can provide vacuum pressure conditions below 10⁻⁸ Torr and vacuum pressure conditions above 10⁻⁸ Torr inside the airlock;
in said module for depositing materials by evaporation using a molecular beam, the face to be treated A of the substrate is oriented towards the lower portion of said module, and in the substrate treatment module, the face to be treated A of the substrate is oriented towards the upper portion of said treatment module, said equipment for fabricating semiconductor wafers including a flipper module that can flip the face to be treated A of the substrate upwards when the substrate is intended to be transferred to a treatment module, or downwards when the substrate is intended to be transferred to a module for depositing materials by evaporation using a molecular beam;
the flipper module is integrated into the central conveyor module;
said flipper module is positioned between one of the ports of the central conveyor module and one of the substrate treatment modules or one of the modules for depositing materials by evaporation using a molecular beam;
said flipper module is integrated into said airlock;
said flipper module comprises a flipper means, and a longitudinal movement means placed between one of said openings of the flipper module and the flipper means, the longitudinal movement means comprising a support that can support the substrate, and that can be moved between a position for unloading or loading the substrate by the flipper means, and a position for evacuating or receiving the substrate through one of the openings of the flipper module, said flipper means being capable of picking up the substrate positioned on the support of the longitudinal movement means, pivoting about a horizontal axis to flip the substrate, and unloading it onto another support;
the flipper means comprises pivot means to flip the substrate and gripper means to pick up and release the substrate, said gripper means comprising two semi-circular arms forming tongs, and articulation means to allow tightening or loosening of the semi-circular arms when the flipper means is in the position for loading or unloading the substrate;
the substrate treatment module or modules comprise at least one etcher module or vapor deposition module for performing CVD, PECVD, PVD, or MOCVD.

The invention thus provides equipment for fabricating semiconductor wafers that is compact and that can be used to carry out all of the steps of deposition and treatment on the semiconductor wafer in situ and under vacuum without transferring the substrate from one piece of equipment to another.

This multiple chamber arrangement can also be used to obtain high productivity, since the steps are carried out in succession without transporting the substrate to another, external, system such as a MBE deposition system.

It is possible to deposit epitaxial semiconductor materials (mono-crystalline), metals (poly crystalline), and insulators (amorphous) in the same equipment and under ultra-vacuum pressure conditions.

It is possible to produce stacks of layers, keeping the interfaces extremely clean, and also novel stacks.

It is possible to produce high performance transistors, by depositing a stack of materials composed of the III-V (AsGa) or II-VI type, for example, on a silicon/germanium layer, then a high permittivity gate oxide (for example La₂Hf₂O₇), and a binary metal (of the TaN type, for example).

The thin layers of materials obtained are of small thickness (a few layers of atoms to a single layer of atoms) and have interfaces resolved to within one atomic monolayer and substantial uniformity of thickness, composition, or doping over large surfaces.

The equipment for fabricating semiconductor wafers can also be used to prevent contamination by metals.

The invention also relates to equipment or a module for depositing materials by evaporation using a molecular beam for fabricating semiconductor wafers comprising a substrate intended to be covered with at least one layer of materials, the substrate comprising a face to be treated A and an untreated face B, the equipment for depositing materials by evaporation using a molecular beam comprising:
a reaction chamber comprising an upper portion and a lower portion;
at least one source of materials positioned in the lower portion of the reaction chamber and directed towards its upper portion;
a sample-carrier positioned in the upper portion of the reaction chamber and capable of supporting the substrate such that said substrate has its face to be treated A oriented towards the source or sources of materials; and
pump means that can provide vacuum pressure conditions below 10⁻⁸ Torr in the reaction chamber.

According to the invention, the equipment for depositing materials by evaporation using a molecular beam comprises:
a flipper module in communication with the reaction chamber, the module being capable of being connected in sealed manner to a semiconductor wafer fabrication equipment set functioning under vacuum pressure conditions above 10⁻⁸ Torr and comprising one or more substrate treatment modules in which the substrate has its face to be treated A oriented towards the upper portion of the module, the flipper module comprising flipper means that can flip the face to be treated A of the substrate upwards when the substrate is intended to be transferred to the semiconductor fabrication equipment set functioning under vacuum pressure conditions above 10⁻⁸ Torr.

The invention provides equipment or a module for molecular beam deposition that is compact and compatible with the multi-chamber systems used in the microelectronics industry, and complies with SEMI standards (SEMI E72-0600, SEMI E6-0303, SEMI E51-0200, SEMI E70-1103, inter alia).

The invention is described in more detail with reference to the accompanying drawings in which:

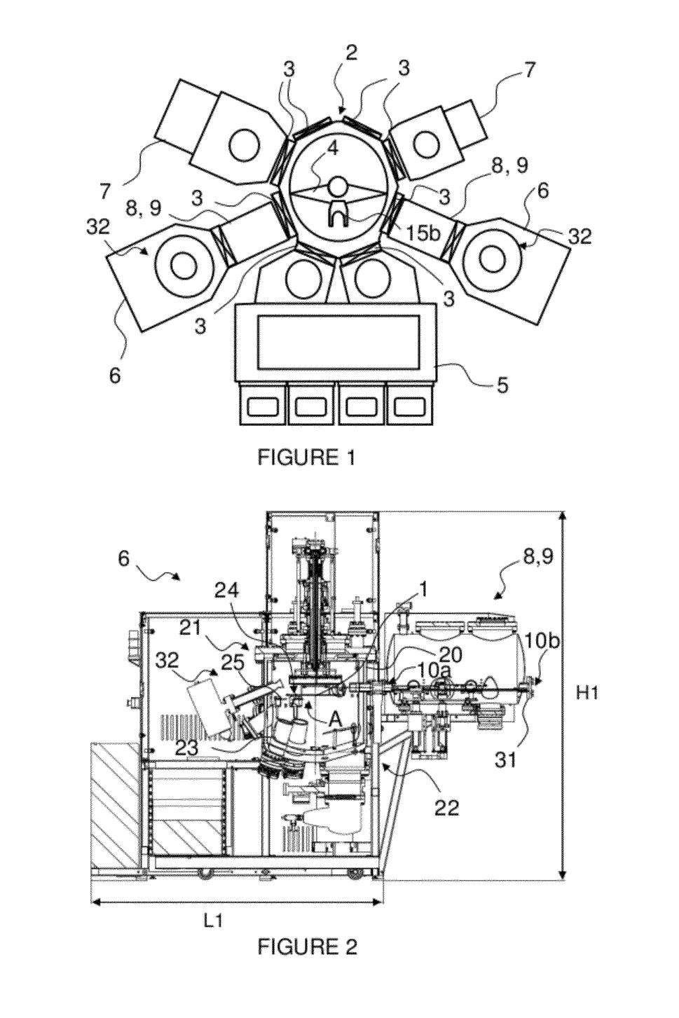

FIG. 1 shows a semiconductor wafer fabrication equipment in accordance with one possible embodiment of the invention;

FIG. 2 is a longitudinal sectional view of equipment or a module for molecular beam deposition, in accordance with one possible embodiment of the invention;

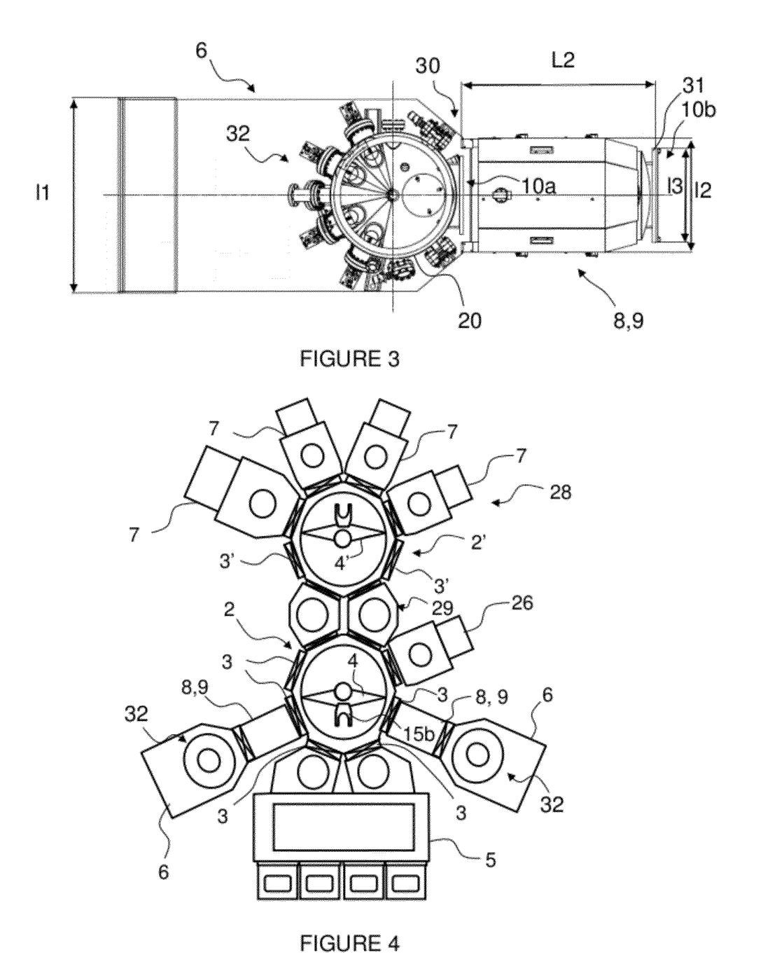

FIG. 3 is a top view of said equipment or module for molecular beam deposition;

FIG. 4 shows equipment for fabricating semiconductor wafers in accordance with another embodiment of the invention;

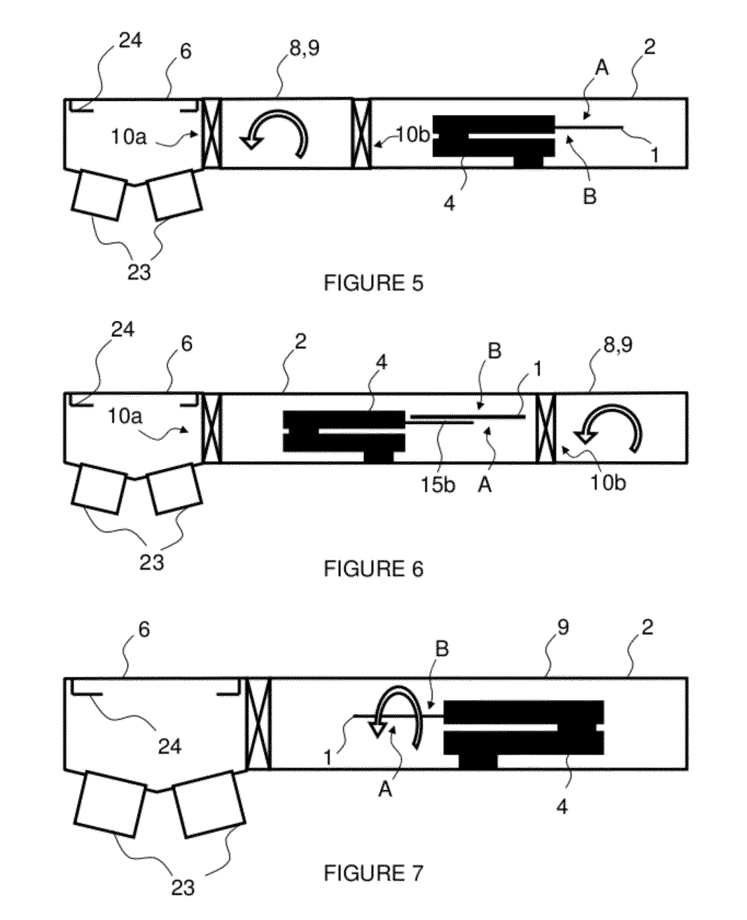

FIG. 5 shows a flipper module in accordance with a first possible arrangement;

FIG. 6 shows a flipper module in accordance with a second possible arrangement;

FIG. 7 shows a flipper module in accordance with a third possible arrangement;

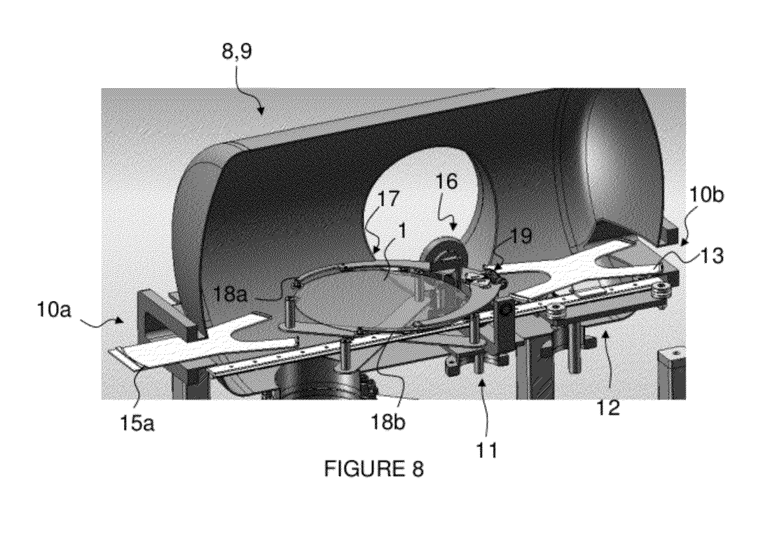

FIG. 8 shows a detail of a flipper module in accordance with one possible embodiment of the invention.

In FIGS. 2 and 3, elements that are not essential to comprehension of the invention are not given reference numerals.

FIG. 1 shows equipment for fabricating semiconductor wafers in accordance with one possible embodiment of the invention.

The term “semiconductor wafer” means a substrate 1 covered with at least one layer of materials and that has undergone various operations to obtain a disk that is then treated to obtain a multitude of electronic or microelectronic devices such as magnetic memories, logic circuits (transistors, microprocessors, dynamic random access memory (DRAM)), infrared detectors, blue light-emitting diodes (LEDs), laser diodes, sensors, or radio-frequency (RF) components, for example. The substrate 1 comprises a face to be treated A and an untreated face B.

The fabrication equipment comprises a plurality of modules or chambers including a central conveyor module 2 including a plurality of lateral ports 3, and conveyor means 4 that can convey the substrate 1 from one lateral port 3 to another. The central conveyor module 2 can function under conditions of vacuum pressure or of pressure above 10⁻⁸ Torr. The central conveyor module 2 complies with SEMI standards.

The term “lateral ports 3” means openings that can communicate with a module in sealed manner. Said openings are preferably rectangular in shape and they may be closed by a valve.

The conveyor means 4 comprise a support 15b that can support the substrate 1 and that can be moved in rotation. The conveyor means 4 are positioned at the center of the central conveyor module 2. The support 15b is also movable in translation. The conveyor means 4 can be used to position the substrate in front of a selected port 3. The valve of the port 3 is open, and so the support is moved in translation towards the module associated with the port 3 to deposit the substrate 1 therein.

In the example of FIG. 1, the central conveyor module 2 is connected to a secondary pump that can reach a pressure of approximately 2×10⁻⁸ Torr.

The fabrication equipment also comprises a loader module 5 connected to one or more ports 3 of the central conveyor module 2. The loader module 5 is capable of receiving one or more substrates 1 of silicon or germanium or other substrates, e.g. having a diameter of 200 mm, 300 mm, or 450 mm, before transferring them to the various modules. The loader module 5 complies with SEMI standards.

The fabrication equipment comprises one or more substrate treatment modules 7 functioning under vacuum pressure conditions above 10⁻⁸ Torr. Each treatment module 7 is connected to one of the ports 3 of the central conveyor module 2 and can receive the substrate 1 in order to carry out a treatment operation on its face to be treated A.

Each substrate treatment module 7 comprises at least one system for chemical vapor deposition (CVD), plasma enhanced chemical vapor deposition (PECVD), physical vapor deposition (PVD), metal organic chemical vapor deposition (MOCVD), heat treatment, or etching, or other treatment.

Said substrate treatment modules 7 are modules that are conventionally used in the microelectronics industry and they comply with SEMI standards.

In said substrate treatment modules 7, the substrate 1 is positioned at the bottom of the module with its face to be treated A directed upwards.

The various modules above form a multi-chamber system used in the microelectronics industry.

The fabrication equipment comprises at least one module for depositing materials by evaporation using a molecular beam 6 functioning under vacuum pressure conditions below 10⁻⁸ Torr. Each module for depositing materials by evaporation using a molecular beam 6 is connected to one of the ports 3 of the central conveyor module 2 and is capable of receiving the substrate 1 in order to deposit a layer of materials on its face to be treated A.

Each piece of equipment or module for depositing materials by evaporation using a molecular beam 6 comprises a MBE or MBD reactor 32.

FIG. 2 is a longitudinal sectional view of a piece of equipment or module for depositing materials by evaporation using a molecular beam 6 comprising a MBE reactor 32.

The MBE reactor 32 comprises a reaction chamber 20 comprising an upper portion 21 and a lower portion 22.

The MBE reactor 32 includes at least one source of materials 23 positioned in the lower portion of the reaction chamber 22 and directed towards its upper portion 21. The source of materials 23 may be a crucible surrounded by a filament or a crucible intended to undergo electron bombardment in order to evaporate the material to be vaporized.

The MBE reactor 32 includes a sample-carrier 24 positioned in the upper portion 21 of the reaction chamber and capable of supporting the substrate 1 so that its face to be treated A is oriented towards the source or sources of materials 23.

The majority of the materials are in the liquid state during evaporation, and so the crucible is placed approximately vertically in the bottom of the reaction chamber.

The MBE reactor 32 includes flaps 25 to block off the sources of materials 23.

The MBE reactor 32 includes pump means (not shown) that can provide vacuum pressure conditions below 10⁻⁸ Torr in the reaction chamber. The pressure in the reaction chamber 22 is preferably below 10⁻⁹ Torr.

The module for depositing materials by evaporation using a molecular beam 6 includes an airlock 8 connecting it to one of the ports 3 of the central conveyor module 2. More precisely, the airlock 8 connects one of the ports 3 of the central conveyor module 2 to the reaction chamber 20 of the module for depositing materials by evaporation using a molecular beam 6, as shown in FIG. 5.

The airlock 8 can render the pressure of the module for depositing materials by evaporation using a molecular beam 6 compatible with the central conveyor module 2.

As shown in FIG. 8, the airlock 8 includes an opening 10a, 10b at each of its lateral ends, and pump means to allow it to be opened alternately onto modules with vacuum pressure conditions below 10⁻⁸ Torr or vacuum pressure conditions above 10⁻⁸ Torr. Said pump means comprise primary and secondary pumps. A pressure sensor is also provided. Each opening 10a, 10b may be closed in sealed manner by a valve, and is preferably rectangular in shape.

The airlock 8 can be used to place the central conveyor module 2 in communication with the module for depositing materials by evaporation using a molecular beam 6, which are at different pressures. The airlock 8 complies with SEMI standards.

The semiconductor wafer fabrication equipment includes a flipper module 9 that can flip the face to be treated A of the substrate 1 upwards when the substrate 1 is intended to be transferred to a treatment module 7, or downwards when the substrate 1 is intended to be transferred to a module for depositing materials by evaporation using a molecular beam 6.

In one embodiment of the invention, the airlock 8 includes the flipper module 9, as shown in FIGS. 1, 5 and 8.

In the module for depositing materials by evaporation using a molecular beam 6, the substrate 1 is positioned in the upper portion of the module 21, and the face to be treated A of the substrate 1 is oriented towards the lower portion 22 of the module for depositing materials by evaporation using a molecular beam 6. In the substrate treatment module 7, however, the face to be treated A of the substrate 1 is oriented towards the upper portion of the treatment module 7. The flipper module 9 can thus be used to orient the face to be treated A of the substrate 1 as a function of the module that is to be used to carry out an operation on that face A.

As shown in FIG. 8, the flipper module 9 comprises a flipper means 11, and a longitudinal movement means 12 placed between one of the openings 10a, 10b of the flipper module 9 and the flipper means 11. This opening 10b is in communication with the reaction chamber 20 of the module for depositing materials by evaporation using a molecular beam 6.

The longitudinal movement means 12 includes a support 13 that can support the substrate 1, and that can move between a position for unloading or loading the substrate 1 by the flipper means 11, and a position for evacuating or receiving the substrate 1 through one of the openings of the flipper module 10a, 10b. More precisely, this opening 10a, 10b corresponds to the opening that is in communication with the reaction chamber 20 of the module for depositing materials by evaporation using a molecular beam 6.

The flipper means 11 is capable of picking up the substrate 1 positioned on the support 13 of the longitudinal movement means, of pivoting about a horizontal axis to flip the substrate 1, and of unloading it onto a fixed support 15a. Another longitudinally movable support 15b is capable of picking up the substrate 1 from the fixed support 15a. This other longitudinally movable support 15b is attached to the central conveyor module 2.

The flipper means 11 comprises an articulation 16 to flip the substrate 1 and gripper means 17 to pick up and release the substrate 1. The gripper means 17 comprise two semi-circular or near semi-circular arms 18a, 18b, forming tongs, and articulation means 19 to allow tightening or loosening of the semi-circular arms 18a, 18b when the flipper means 11 is in the position for loading or unloading the substrate 1.

The various supports 13, 15a, and 15b have dimensions adapted to substrates 1 with diameters of 200 mm or 300 mm, or others.

FIG. 8 shows an example of a module or equipment for depositing materials by evaporation using a molecular beam 6 comprising such a flipper module 9. This module for depositing materials by evaporation using a molecular beam 6 is surrounded by a protective casing.

An example of operation the flipper module 9 or airlock 8 is described below.

After being loaded onto the support 15b of the central conveyor module 2, the substrate 1 is brought in front of the port 3 associated with a module for depositing materials by evaporation using a molecular beam 6 by the central conveyor module 2. The pressure in the central conveyor module 2 is 10⁻⁷ Torr and the face to be treated A of the substrate is oriented upwards.

The valve of the airlock 8 associated with the port 3 is opened and the substrate 1 is transferred into the airlock 8 via the movable support 15b, the second valve of the airlock 8 associated with the reaction chamber 20 of the module for depositing materials by evaporation using a molecular beam 6 being closed.

The movable support 15b deposits the substrate 1 on the fixed support 15a. The movable support 15b goes back into the conveyor module 2. The valve of the airlock 8 associated with the port 3 is closed. The pump means of the airlock 8 reduce the pressure in the airlock 8 down to 10⁻⁹ Torr or less.

The two semi-circular arms 18a, 18b pick up the substrate 1 from the fixed support 15a. The two semi-circular arms 18a, 18b turn through 180° in order to flip the substrate 1 onto the support 13 of the longitudinal movement means 12. The face to be treated A of the substrate 1 is oriented downwards, i.e. facing the support 13 of the longitudinal movement means 12.

The valve of the airlock 8 associated with the reaction chamber 20 of the module for depositing materials by evaporation using a molecular beam 6 is opened and the substrate 1 is moved in translation longitudinally by the movement means 12 to be deposited on the sample-carrier 24 of the module for depositing materials by evaporation using a molecular beam 6. The face to be treated A of the substrate 1 is oriented downwards, i.e. towards the lower portion 22 of the reaction chamber 20 of the module for depositing materials by evaporation using a molecular beam 6. The movement means 12 is moved in translation into the airlock 8.

The valve of the airlock 8 associated with the reaction chamber 20 of the module for depositing materials by evaporation using a molecular beam 6 is closed again and the operations for depositing the layer of materials can commence.

In the same manner, after deposition is complete, the substrate 1 follows a reversed path and is flipped to the other side by the flipper module 9.

The pressure in the airlock 8 is adapted to the pressure of the central conveyor module 2, becoming 2×10⁻⁸ Torr.

A module for depositing materials by evaporation using a molecular beam 6 is obtained that is compatible as regards pressure with the substrate treatment modules 7 and the central conveyor module 2, functioning under vacuum pressure conditions above 10⁻⁸ Torr.

Other embodiments are possible concerning positing the flipper module 9.

The flipper module 9 may be integrated into the central conveyor module 2, as shown in FIG. 7.

Alternatively, the flipper module 9 may be positioned between one of the ports 3 of the central conveyor module 2 and one of the substrate treatment modules 7, as shown in FIG. 6.

As can be seen in FIG. 1, the semiconductor wafer fabrication equipment may comprise two modules for depositing materials by evaporation using a molecular beam 6, and two substrate treatment modules 7.

FIG. 4 shows another embodiment in which the semiconductor wafer fabrication equipment comprises a first central conveyor module 2 including a plurality of lateral ports 3, and a loader module 5 connected to two of the ports 3 of the central conveyor module 2, which may accommodate at least 15 substrates. These substrates have a diameter or 200 mm or 300 mm.

The semiconductor wafer fabrication equipment comprises two modules for depositing materials by evaporation using a molecular beam 6 including a module having a reaction chamber 20 dedicated depositing a layer of semiconductor alloys (group III-V) from sources of solid or gaseous arsenic, gallium, or indium, and one module having a reaction chamber 20 dedicated to depositing a layer of oxide (insulating and dielectric materials). This module is equipped with sources of plasma materials and allows the metals to be nitrided or oxidized.

The semiconductor wafer fabrication equipment also includes a surface analysis module 26.

The semiconductor wafer fabrication equipment comprises a set of substrate treatment modules 28 comprising second conveyor means 4′, and a second central conveyor module 2′ comprising a plurality of lateral ports 3′ connected to one or more lateral ports 3 of the central conveyor module 2.

The lateral ports 3′, 3 of the first and second conveyor means 4, 4′ have a rectangular shaped connection interface provided with a rectangular opening that is adapted to pass a substrate 1 that is 200 mm or 300 mm in diameter.

The second central conveyor module 2′ is in communication with a plurality of substrate treatment modules 7 including at least a PVD module and an etcher module, via an intermediate transfer module 29. Said intermediate transfer module 29 can be used to transfer the substrate 1 from one central conveyor module 2, 2′ to another.

The etcher module can be used to prepare the oxide layer surface.

The PVD module can be used to deposit metallic layers to produce conductive electrodes over the oxide layer.

An analysis module may be provided for use in carrying out X-ray photoelectron spectroscopy (XPS), or reflection high-energy electron beam diffraction (RHEED), or near field atomic force microscopy (AFM) or scanning tunneling microscopy (STM) to perform characterizations.

The arrangement described above is one possible example. Other arrangements are also possible.

The semiconductor wafer fabrication equipment can be used to deposit elements such as Si, Hf, Ta, La, Ti, As, Ga, Sb and In, for example. It is possible to produce reactive deposits by forming TaN, TiN, HfO₂, for example.

The dimensions of the module or equipment for molecular beam deposition 6 for fabricating semiconductor wafers are small compared with known equipment. Its height is less than 3.5 m [meter]. Its length is less than 2.8 m and its width is less than 1.2 m. It weighs less than 6000 kg [kilogram].

The dimensions of the module for depositing materials by evaporation using a molecular beam 6 comply with SEMI standards and more particularly with the standard SEMI E72-0600.

In the example of FIGS. 2 and 3, the module for depositing materials by evaporation using a molecular beam 6, provided with its protective casing or casings, has a length L1 of 1844.5 mm, a width l1 of 1000 mm and a height H1 of 2367 mm.

The flipper module 9, provided with its protective casing, has a length L2 of 998.5 mm and a width l2 of 582 mm.

The flipper module 9 comprises a connection interface 31 comprising the opening of the flipper module 10b intended to be associated with a molecular beam deposition module 6. Said connection interface 31 has a width l3 of 480 mm.

The set comprising the molecular beam deposition module 6 and the flipper module 9 has a total length Lₜₒₜₐₗ of approximately 2763 mm.

Compared with prior art systems, the molecular beam deposition module 6 of the invention presents sources of materials 23 and other elements, such as the precursor gas injectors, that are arranged differently about the module.

The various sources of materials 23 are not distributed regularly around the reaction chamber 20 of the molecular beam deposition module 6.

A zone at the periphery of the reaction chamber 30 is not provided with a source of materials 23 or other elements in order to allow access to the airlock 8 and to facilitate maintenance operations on the sources of materials 23 and the airlock 8.

1. Equipment for fabricating semiconductor wafers, each comprising a substrate (1) covered with at least one layer of materials, said substrate (1) comprising a face to be treated (A) and an untreated face (B), said fabricating equipment comprising:
a central conveyor module (2) comprising a plurality of lateral ports (3) and conveyor means (4) that can convey said substrate (1) from one lateral port (3) to another, said central conveyor module (2) being capable of functioning under vacuum pressure conditions above 10⁻⁸ Torr;
a loader module (5) connected to one or more ports (3) of the central conveyor module (2), said loader module (5) being capable of receiving one or more substrates (1); and
one or more treatment modules (7) for treating the substrate functioning under vacuum pressure conditions above 10⁻⁸ Torr, each treatment module (7) being connected to one of the ports (3) of the central conveyor module (2) and being capable of receiving said substrate (1) in order to carry out a treatment operation on its face to be treated (A), at least one of said substrate treatment modules (7) comprising a system for depositing materials;
the equipment being characterized in that it comprises:
at least one molecular beam deposition module for depositing materials by evaporation using a molecular beam (6) functioning under vacuum pressure conditions below 10⁻⁸ Torr, said molecular beam deposition module (6) being connected to one of the ports (3) of the central conveyor module (2) and being capable of receiving said substrate (1) in order to deposit a layer of materials on its face to be treated (A).

2. Semiconductor wafer fabrication equipment according to claim 1, characterized in that said module for depositing materials by evaporation using a molecular beam (6) includes an airlock (8) connecting it to one of the ports (3) of the central conveyor module (2), said airlock (8) allowing the pressure between the module for depositing materials by evaporation using a molecular beam (6) to be made compatible with the central conveyor module (2), said airlock (8) including an opening (10a, 10b) in each of its lateral ends that can be closed by a valve, and pump means that can provide vacuum pressure conditions below 10⁻⁸ Torr and vacuum pressure conditions above 10⁻⁸ Torr inside the airlock (8).

3. Semiconductor wafer fabrication equipment according to claim 1, characterized in that in said module for depositing materials by evaporation using a molecular beam (6), the face to be treated (A) of the substrate (1) is oriented towards the lower portion (22) of said module (6), and in that in the substrate treatment module (7), the face to be treated (A) of the substrate (1) is oriented towards the upper portion of said treatment module (7), said equipment for fabricating semiconductor wafers including a flipper module (9) that can flip the face to be treated (A) of the substrate (1) upwards when the substrate (1) is intended to be transferred to a treatment module (7), or downwards when the substrate (1) is intended to be transferred to a module for depositing materials by evaporation using a molecular beam (6).

4. Semiconductor wafer fabrication equipment according to claim 3, characterized in that the flipper module (9) is integrated into the central conveyor module (2).

5. Semiconductor wafer fabrication equipment according to claim 3, characterized in that said flipper module (9) is positioned between one of the ports (3) of the central conveyor module (2) and one of the substrate treatment modules (7).

6. Semiconductor wafer fabrication equipment according to claim 3, characterized in that said flipper module (9) is positioned between one of the ports (3) of the central conveyor module (2) and one of the modules for depositing materials by evaporation using a molecular beam (6), said flipper module (9) being integrated into said airlock (8).

7. Semiconductor wafer fabrication equipment according to claim 5, characterized in that said flipper module (9) comprises a flipper means (11) and longitudinal movement means (12) placed between one of said openings (10a, 10b) of the flipper module (9) and the flipper means (11), the longitudinal movement means (12) comprising a support (13) that can support the substrate (1) and that can be moved between a position for unloading or loading the substrate (1) by the flipper means (11) and a position for evacuating or receiving the substrate (1) through one of the openings of the flipper module (10a, 10b), said flipper means (11) being capable of picking up the substrate (1) positioned on the support (13) of the longitudinal movement means, pivoting about a horizontal axis to flip the substrate (1), and unloading it onto another support (15a).

8. Semiconductor wafer fabrication equipment according to claim 7, characterized in that the flipper means (11) comprises pivot means (16) to flip the substrate and gripper means (17) to pick up and release the substrate (1), said gripper means (17) comprising two semi-circular arms (18a, 18b) forming tongs, and articulation means (19) to allow tightening or loosening of the semi-circular arms (18a, 18b) when the flipper means (11) is in the position for loading or unloading the substrate (1).

9. Semiconductor wafer fabrication equipment according to claim 1, characterized in that the substrate treatment module or modules (7) comprise at least one etcher module or vapor deposition module for performing CVD, PECVD, PVD, or MOCVD.

10. Equipment for depositing materials by evaporation using a molecular beam (6) for fabricating semiconductor wafers comprising a substrate (1) intended to be covered with at least one layer of materials, the substrate (1) comprising a face to be treated (A) and an untreated face (B), said equipment for depositing materials by evaporation using a molecular beam (6) comprising:
a reaction chamber (20) comprising an upper portion (21) and a lower portion (22);
at least one source of materials (23) positioned in the lower portion (22) of the reaction chamber and directed towards its upper portion (21);
a sample-carrier (24) positioned in the upper portion (21) of the reaction chamber and capable of supporting said substrate (1) such that said substrate has its face to be treated (A) oriented towards the source or sources of materials (23); and
pump means that can provide vacuum pressure conditions below 10⁻⁸ Torr in the reaction chamber (20);
the equipment being characterized in that it comprises:
a flipper module (9) in communication with the reaction chamber (20), the module being capable of being connected in sealed manner to a semiconductor wafer fabrication equipment set functioning under vacuum pressure conditions above 10⁻⁸ Torr and comprising one or more substrate treatment modules (7) in which the substrate (1) has its face to be treated (A) oriented towards the upper portion of said module, said flipper module (9) comprising flipper means (11) that can flip the face to be treated (A) of the substrate (1) upwards when the substrate (1) is intended to be transferred to the semiconductor fabrication equipment set functioning under vacuum pressure conditions above 10⁻⁸ Torr.

11. Semiconductor wafer fabrication equipment according to claim 2, characterized in that in said module for depositing materials by evaporation using a molecular beam (6), the face to be treated (A) of the substrate (1) is oriented towards the lower portion (22) of said module (6), and in that in the substrate treatment module (7), the face to be treated (A) of the substrate (1) is oriented towards the upper portion of said treatment module (7), said equipment for fabricating semiconductor wafers including a flipper module (9) that can flip the face to be treated (A) of the substrate (1) upwards when the substrate (1) is intended to be transferred to a treatment module (7), or downwards when the substrate (1) is intended to be transferred to a module for depositing materials by evaporation using a molecular beam (6).

12. Semiconductor wafer fabrication equipment according to claim 6, characterized in that said flipper module (9) comprises a flipper means (11) and longitudinal movement means (12) placed between one of said openings (10a, 10b) of the flipper module (9) and the flipper means (11), the longitudinal movement means (12) comprising a support (13) that can support the substrate (1) and that can be moved between a position for unloading or loading the substrate (1) by the flipper means (11) and a position for evacuating or receiving the substrate (1) through one of the openings of the flipper module (10a, 10b), said flipper means (11) being capable of picking up the substrate (1) positioned on the support (13) of the longitudinal movement means, pivoting about a horizontal axis to flip the substrate (1), and unloading it onto another support (15a)

13. Semiconductor wafer fabrication equipment according to claim 2, characterized in that the substrate treatment module or modules (7) comprise at least one etcher module or vapor deposition module for performing CVD, PECVD, PVD, or MOCVD.

14. Semiconductor wafer fabrication equipment according to claim 3, characterized in that the substrate treatment module or modules (7) comprise at least one etcher module or vapor deposition module for performing CVD, PECVD, PVD, or MOCVD.

15. Semiconductor wafer fabrication equipment according to claim 4, characterized in that the substrate treatment module or modules (7) comprise at least one etcher module or vapor deposition module for performing CVD, PECVD, PVD, or MOCVD.

16. Semiconductor wafer fabrication equipment according to claim 5, characterized in that the substrate treatment module or modules (7) comprise at least one etcher module or vapor deposition module for performing CVD, PECVD, PVD, or MOCVD.

17. Semiconductor wafer fabrication equipment according to claim 6, characterized in that the substrate treatment module or modules (7) comprise at least one etcher module or vapor deposition module for performing CVD, PECVD, PVD, or MOCVD.

18. Semiconductor wafer fabrication equipment according to claim 7, characterized in that the substrate treatment module or modules (7) comprise at least one etcher module or vapor deposition module for performing CVD, PECVD, PVD, or MOCVD.

19. Semiconductor wafer fabrication equipment according to claim 8, characterized in that the substrate treatment module or modules (7) comprise at least one etcher module or vapor deposition module for performing CVD, PECVD, PVD, or MOCVD.
